(19) United States
(12) Patent Application Publication
(10) Pub. No.: US 2015/0207070 A1
(43) Pub. Date: Jul. 23, 2015

(54) Antimony-Rich High-speed Phase-change Material Used In Phase-Change Memory, Preparing Method, And Application Thereof

(71) Applicant: SHANGHAI INSTITUTE OF MICROSYSTEM AND INFORMATION TECHNOLOGY, CHINESE ACADEMY, SHANGHAI (CN)

(72) Inventors: Zhitang Song, Shanghai (CN); Liangcai Wu, Shangcai (CN); Cheng Peng, Shanghai (CN); Feng Rao, Shanghai (CN); Min Zhu, Shanghai (CN)

(21) Appl. No.: 14/129,957

(22) PCT Filed: Dec. 27, 2012
(86) PCT No.: PCT/CN2012/087596

§ 371 Date: Dec. 28, 2013

(30) Foreign Application Priority Data
Sep. 11, 2012 (CN) 20121033521.8

(51) Int. Cl. H01L 45/00; C23C 14/34; C23C 14/35

(52) U.S. Cl. CPC H01L 45/144; H01L 45/06; H01L 45/1616; H01L 45/1625; C23C 14/35; C23C 14/3464

(57) ABSTRACT

The present invention relates to a metal element doped phase-change material in the field of micro-electronics technologies, specifically to an antimony-rich high-speed phase-change material used in a phase-change memory (PCRAM), a preparing method and an application thereof. The antimony-rich high-speed phase-change material used in a PCRAM has a chemical formula being Aₓ(Sb₂Te)₁₋ₓ, x is an atom percent, where A is selected from W, Ti, Ta, and Mn, and 0<x<0.5 The phase-change material provided in the present invention is similar to a usual GeSbTe material, so as to be propitious to implement high-density storage. The material may perform reversible phase-change under an effect of an externally electrically driven nano-second (ns) pulse. A phase-change speed of the W—Sb—Te is 3 times of the GeSbTe material, so as to be propitious to implement the high-speed PCRAM.

### BACKGROUND OF THE PRESENT INVENTION

1. Field of Invention

The present invention relates to a metal element doped phase-change material in the field of micro-electronics technologies, specifically to an antimony-rich high-speed phase-change material used in a phase-change memory (PCRAM), a preparing method and an application thereof.

2. Description of Related Arts

The phase-change storage technology, being a newly developed large capacity storage technology, has the high speed, the high density, the low voltage, the low power consumption, and the good fatigue characteristic, so as to become a main force for replacing the existing non-volatile storage technology. In recent years, research of a PCRAM becomes a hot spot in the science filed. A working principle of the PCRAM is quite simple, where storage of “0” and “1” is implemented by using the great resistance different value of the phase-change material in the non crystalline state and the crystalline state. Although the performance of the phase-change material is found in 60s of the last century, as the technical conditions are limited, the phase-change storage technology cannot show the competitive advantage. In recent ten years, with the high-speed development of the micro-electronics technology, advantages of the PCRAM become distinct. The PCRAM may break the limit of the physical limit of a conventional CMOS memory, and perform the stable phase-change operation in the nano-meter level, so as to show a strong application prospect. Recently, Intel completes mass production of a PCRAM chip on a 45 nm node, and integrates the PCRAM chip with the DRAM to form a new memory. Sumsung of Korea will perform mass production of the PCRAM on a 22 nm node. It may be known that the trend that the PCRAM technology is used as the main stream storage technology is increasingly distinct.

The phase-change material, being a core part of the work of the PCRAM, nearly decides all characteristics of the PCRAM, so that the research of the phase-change material is indispensable. In the phase-change materials, Ge₂Sb₂Te₅ in ternary system Ge—Sb—Te materials and GeTe in binary system Ge—Te materials are typical phase-change materials and have excellent comprehensive performances. However, it is found during application that the Ge₂Sb₂Te₅ material has a relatively great density change during the phase-change. A crystallization speed is poor, being generally hundreds of nano-seconds (ns), a crystallization temperature is relatively low, being approximately 160° C., a ten-year holding temperature is approximately 80° C., and an operation voltage is relatively high. The disadvantages seriously block wide application of the material in the phase-change storage field. The crystallization temperature of GeTe is higher than Ge₂Sb₂Te₅, a resistance difference before and after the phase-change is great, the speed during the current operation may reach several nano-seconds, but a melting point of GeTe is approximately up to 720° C., even the operation power consumption is greater than Ge₂Sb₂Te₅, and the data holding capability cannot satisfy the demands of the industry field and the military space flight field. To sum up, the development direction of the PCRAM is to find a phase-change material with a quick phase-change speed, a low melting point, and good data holding capability. The binary system material Sb₂Te has a δ phase in the Sb—Te binary system phase diagram, the phase has a stable hexagonal crystallization structure, and the crystalline state Sb₂Te material is formed by superposing Sb₂Te₃ and Sb₂ layers, where the Sb₂ layer may accelerate the crystallization speed of the material. In addition, a melting point of the Sb—Te material in the δ phase is approximately 540° C. which is much lower than Ge₂Sb₂Te₅, and the resistance change before and after the phase-change is up to 4 orders of magnitude. However, the only disadvantage of Sb₂Te is that the crystallization temperature is relatively low, being approximately 145° C. Therefore, Sb₂Te cannot satisfy the demand of the application, especially the application for certain high-temperature environments. In order to compensate the disadvantage, other elements are doped to change characteristics of the material.

### SUMMARY OF THE PRESENT INVENTION

In view of disadvantages or defects in the prior art, an object of the present invention is to provide a phase-change material with excellent comprehensive performance and being compatible with a CMOS technique.

In a first aspect, the present invention provides an antimony-rich high-speed phase-change material used in a PCRAM, having a chemical formula being Aₓ(Sb₂Te)₁₋ₓ, x is an atom percent, where A is selected from W, Ti, Ta, and Mn.

Preferably, 0<x<0.5

Preferably, 0<x≦0.12.

Preferably, A is selected from W.

In the phase-change storage material Aₓ(Sb₂Te)₁₋ₓ consistent with the present invention, A element may be a metal element, such as W, Ti, Ta, or Mn, which may achieve the same technical effect.

Preferably, the phase-change material provided in the present invention is a single-phase W—Sb—Te material.

The phase-change material provided in the present invention is similar to a usual GeSbTe material, so as to be propitious to implement high-density storage. The material may perform reversible phase-change under an effect of an externally electrically driven nano-second level pulse. A phase-change speed of the W—Sb—Te phase-change material is 3 times of the GeSbTe material, so as to be propitious to implement the high-speed PCRAM. In the phase-change material, through a chemical bond formed by W and Te, a crystallization temperature and heat stability of a non crystalline state may be improved, an element proportion of Sb—Te is fixed, content of W is adjusted, so as to obtain low melting point phase-change storage materials with different crystallization temperatures and different crystallization activation energies.

Under an effect of an electric pulse, the Wₓ(Sb₂Te)₁₋ₓ phase-change storage material consistent with the present invention may quickly transit from the non crystalline state to a stable hexagonal structure without an intermediate state. Resistances before and after the phase-change are stable, and the reversible phase-change of the material may be completed with a relatively low energy. After the crystallization, W atoms are uniformly distributed in crystal lattices of Sb₂Te, and the entire material has a united hexagonal crystallization structure without phase separation, thereby improving reliability of the device and being suitable for high-density storage. In the phase-change storage material, the W—Te bond existing in the material changes physical properties of the material, so as to greatly improve the heat stability. Therefore, the present invention inherits the advantages of the phase-change material Sb₂Te, such as high-speed and low melting point, meanwhile, the present invention has a smaller volume change before and after the phase-change, and can relatively stably work under a high temperature.

The Wₓ(Sb₂Te)₁₋ₓ phase-change storage material consistent with the present invention may implement the reversible phase-change between high and low resistance states through an external electric pulse, and implement a storage function through a difference between resistance values before and after the change.

In the phase-change storage material Wₓ(Sb₂Te)₋ₓ consistent with the present invention, electro-negativities of W, Sb, and Te elements are respectively 236, 2.1, and 2.1, an electro-negativity difference value between W—Te atoms is greater than Sb—Te, so as to increase a nucleation frequency of an original Sb—Te material, accelerate a crystallization speed, and implement the high-speed phase-change. Meanwhile, the crystal grain size is reduced, and scattering of a crystal grain boundary to charge carriers is increased, so as to improve a crystalline state resistance and lower power consumption.

In the phase-change storage material Wₓ(Sb₂Te)₁₋ₓ consistent with the present invention, the W atoms may lower a non crystalline state electrical conduction activation energy of the material, so that a forbidden band difference value of the material before and after the phase-change is reduced, so as to lower the energy required by the reversible phase-change. In addition, the W atom is relatively heavier than the Sb atom and the Te atom, and under the effect of the electric pulse, the W atom is difficultly shifted, so that during the crystallization process, the W atom may block the diffusion of the Sb atom and the Te atom, so as to reduce component segregation and improve a fatigue characteristic of a phase-change unit.

In a second aspect, the present invention provides a preparing method of an antimony-rich high-speed phase-change material, which comprises magnetron sputtering, chemical vapor deposition (CVD), atom-layer deposition, pulsed laser deposition, electron beam evaporation, electroplating and so on.

Preferably, the preparing method is selected from the magnetron sputtering. When preparing a phase-change thin film, the magnetron sputtering is relatively more flexible. W, Sb, and Te targets co-sputtering may be used, each component may be adjusted by controlling a source power of each target position. Further, W target and Sb₂Te alloy target co-sputtering may also be used. Alternatively, prepared Wₓ(Sb₂Te)₁₋ₓ alloy target single-target sputtering may be used for implementation. All of the methods may be used too prepare the antimony-rich W—Sb—Te high-speed phase-change material according to a proportion of each component in a chemical composition formula.

Preferably, specific steps of the magnetron sputtering are: a Wₓ(Sb₂Te)₁₋ₓ thin film is prepared on a silicon substrate after being thermo-oxidized by using W and Sb₂Te dual-target co-sputtering, where during the co-sputtering, a background vacuum degree is 1.8-2.2×10⁻⁴ Pa, an argon air pressure during sputtering is 0.18-0.26 Pa, a sputtering power of the Sb₂Te target is radio frequency (RF) 20 W, and a sputtering power of the W target is RF 5-10 W.

The preparing technique of the phase-change storage material Wₓ(Sb₂Te)₁₋ₓ consistent with the present invention is mature, and compatibility between various elements and CMOS is good.

In a third aspect, the present invention provides an application of an antimony-rich high-speed phase-change material in a phase-change thin film material field.

In the phase-change storage material consistent with the present invention, on the basis of Sb₂Te, W element is suitably doped to prepare the high-performance phase-change thin film, where the preparing technique is mature, and compatibility between various elements and CMOS is good.

In the phase-change storage material Wₓ(Sb₂Te)₁₋ₓ consistent with the present invention, a crystallization speed may be accelerated after low-temperature heat treatment, so as to improve an operation speed of a phase-change unit.

Preferably, the low-temperature heat treatment method is that: an annealing process of 150° C. is performed for 2 minutes, so that a non crystalline state material structure is more close to a crystalline state or a prepared device is scanned by using a low voltage of 0.2 V-0.5 V.

In a fourth aspect, the present invention provides a phase-change storage device unit prepared by using an antimony-rich high-speed phase-change material.

Preferably, a preparing method of the phase-change storage device unit is a 0.13 μm complementary metal-oxide-semiconductor (CMOS) technique.

Preferably, the preparing method of the phase-change storage device unit specifically comprises the following steps of: depositing an SiO₂ dielectric layer with a thickness of 8-12 nm on a W electrode, making a small hole with a width of 8-12 nm on the SiO₂ dielectric layer right above the W electrode by using ion beam focusing, then filling the hole with the Wₓ(Sb₂Te)₁₋ₓ phase-change material by using CVD or physical vapor deposition (PVD), and finally depositing a TiN adhesion layer with a thickness of 15-25 nm and an Al top electrode with a thickness of 290-310 nm by using the PVD.

In the phase-change storage device unit consistent with the present invention, a phase-change region is reduced to a nano-meter magnitude in a manner of opening and filling the hole, so as to increase a surface area/volume ratio of the phase-change material, and change a material crystallization mechanism by using an interface effect, thereby accelerating a phase-change speed.

Under a nano-second level voltage pulse, the phase-change storage device unit presents a reversible phase-change characteristic. By adopting the antimony-rich W—Sb—Te high-speed phase-change material consistent with the present invention, the phase-change may be quickly performed under an effect of an electric pulse, and “0” and “1” may be distinctly recognized before and after the phase-change. Further, under a relatively short and low voltage pulse, the phase-change storage device unit may stably and repeatedly work for more than 10⁵ times, and high and low resistance values nearly remain unchanged, thereby having good reliability.

### BRIEF DESCRIPTION OF THE DRAWINGS

FIG. 1 is a variation relation curve of Wₓ(Sb₂Te)₁₋ₓ phase-change thin film block resistances with different tungsten contents along with temperature.

FIG. 2 is a contrast between a crystallization speed curve of each sample in Embodiment 1 and Ge₂Sb₂Te₅; and FIG. 3 is a contrast between an Arrhenius curve of each sample in Embodiment 1 and Ge₂Sb₂Te₅.

FIG. 4 is a diffraction diagram of an X ray of a crystalline state of a#, b#, and c# samples.

FIG. 5 is a schematic diagram of a phase-change storage unit with a limited T shape structure in Embodiment 1.

FIG. 6 is a resistance-voltage curve and a resistance-pulse curve of a phase-change storage unit with a T shape structure based on a c# sample in Embodiment 1.

FIG. 7 is a cycle life curve of a phase-change storage unit with a T shape structure based on a c# sample in Embodiment 1.

### DETAILED DESCRIPTION OF THE PREFERRED EMBODIMENTS

Implementation manners of the present invention are illustrated below through specific examples, and persons skilled in the art may easily understand other advantages and efficacies of the present invention through the disclosure of this specification. The present invention may further be implemented or applied through additional different specific implementation manners, various modifications or changes may also be made to details in this specification without departing from the spirit of the present invention based on different viewpoints and applications.

It should be noted that all technical equipment or devices not specifically specified in the following embodiments adopt general equipment or devices in the art; and all voltage values and ranges refer to the absolute voltage.

In addition, it should be understood that one or more method steps mentioned in the present invention do not exclude that other method steps may exist before and after the combined steps, or other method steps may be inserted between the distinctly mentioned steps, except additional description is given; it should be understood that a combined connection relation among one or more equipment/devices mentioned in the present invention does not exclude that other equipment/devices may exist before and after the combined equipment/devices, or other equipment/devices may be inserted between the two distinctly mentioned equipment/devices, except additional description is given. Further, except additional description is given, the number of each method step is only a convenient tool for distinguishing each method step, instead of limiting an arrangement order of each method step or limit an implementation scope of the present invention. Changes or adjustment of a relative relation without substantially changing technical content should be considered to be in the implementation scope of the present invention.

### Embodiment 1

1. A Wₓ(Sb₂Te)₁₋ₓ thin film is prepared on a silicon substrate after being thermo-oxidized by using W and Sb₂Te dual-target co-sputtering which belongs to magnetron sputtering, where during the co-sputtering, a background vacuum degree is 2.0×10⁻⁴ Pa, and an argon air pressure during sputtering is 0.22 Pa. A sputtering power of the Sb₂Te target is fixed at RF 20 W, and sputtering powers of the W target are changed, respectively being RF 0 W, 5 W, 7 W, and 10 W, so as to obtain 4 types of phase-change thin films a#, b#, c#, and d# with different W doping concentrations. Parameters of the 4 types of phase-change thin films are shown in Table 1 in the following.

TABLE 1

| Sample | | Film growing time | Atom percent x in |
|---|---|---|---|
| number | Source power | (min)/film thickness (nm) | Wₓ(Sb₂Te)₁₋ₓ |
| a# | W: RF 0 W | 40/159 | 0 |
| | Sb₂Te: RF 20 W | | |
| b# | W: RF 5 W | 40/154 | 0.03 |
| | Sb₂Te: RF 20 W | | |
| c# | W: RF 7 W | 40/139 | 0.07 |
| | Sb₂Te: RF 20 W | | |
| d# | W: RF 10 W | 40/149 | 0.12 |
| | Sb₂Te: RF 20 W | | |

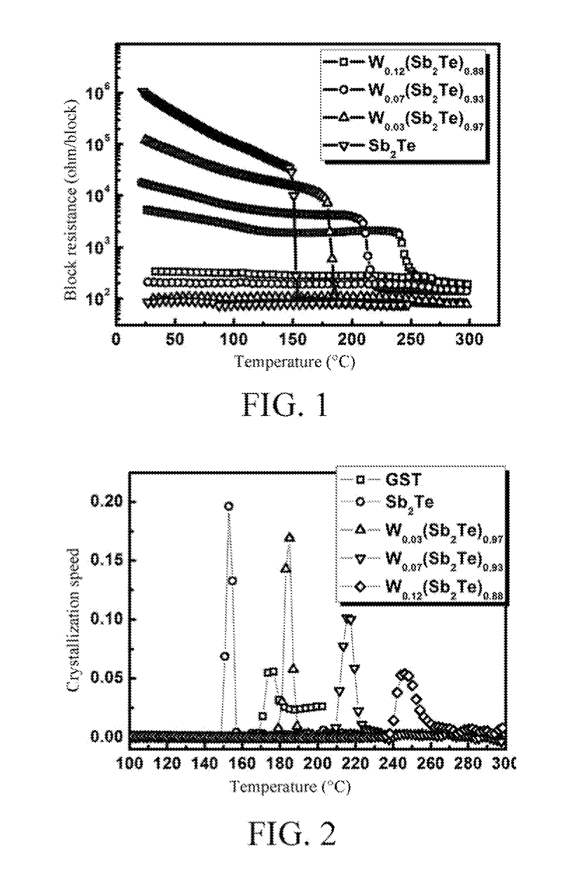

2. An original position resistance test is performed on the Wₓ(Sb₂Te)₁₋ₓ thin film material obtained in step 1, which is grown on an oxidation piece and in which an annealing process is not performed, a result is shown in FIG. 1. It may be known that a crystallization temperature of Sb₂Te in which W is not doped is 145° C. After the W element is doped, the crystallization temperature of the phase-change thin film is greatly improved, in which the crystallization temperature of the d# thin film is up to 241° C., so it may be known that heat stability is distinctly improved. In addition, the crystalline state resistance tends to be greater with the increasing of the doping content of W, which critical affecting the lowering of the power consumption of the device.

3. Each curve in FIG. 1 is substituted to a crystallization index formula for calculation, so as to obtain a crystallization speed curve of each sample, as shown in FIG. 2, where GST represents Ge₂Sb₂Te₅. A maximum value of each curve represents the crystallization speed of the material. It may be known from the drawing that as the W content is increased, the crystallization speed is reduced, but the crystallization speed of the b# sample and the crystallization speed of the c# sample are still 3 times and 2 times of GST. Therefore, it shows that the Wₓ(Sb₂Te)₁₋ₓ, as a new material for replacing GST, is more advantageous in the phase-change speed.

4. According to an Arrhenius equation, an activation energy (Eₐ) and a 10-year holding temperature (T_{10y}) are deduced, and a result is shown in FIG. 3. A specific experiment method is described in the following: firstly, an original position resistance test under different constant temperatures is performed on the each sample obtained in step 1, which is grown on an oxidation piece and in which an annealing process is not performed, a resistance-time curve is recorded, and then failure time (here, the failure time is defined to be time when a normalized resistance value is lowered to 0.5) under the constant temperature is obtained in the resistance-time curve; finally, Eₐ and Ti_{10y a} are deduced by using the Arrhenius equation, so as to obtain a result as shown in FIG. 3 (GST in the drawing is Ge₂Sb₂Te₅). It may be obtained from FIG. 3 that Eₐ of the a# sample is 2.03 e V, and Ti_{10y} is 52° C. After W is doped, a holding capability and the activation energy are distinctly improved, and Ea of the d# sample is 5.13 e V, and the Ti_{10y} is up to 173° C. It indicates that the Wₓ(Sb₂Te)₁₋ₓ thin film after W is doped may improve the holding capability of the phase-change material, so as to enable the phase-change material to relatively stably work under the high temperature.

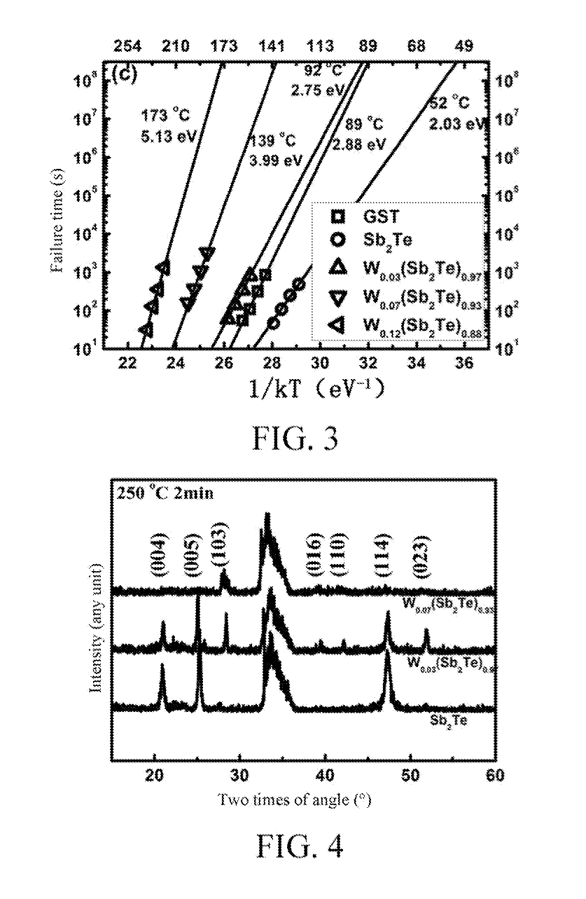

5. The annealing process is performed on the a#, the b#, and the c# samples under 250° C. for 2 min, an X ray diffraction test is performed, and a result is shown in FIG. 4. It may be known that each sample is crystallized. As the W content is increased, intensity of a diffraction peak is distinctly lowered, which indicates that size of a crystal grain is reduced. Through comparison with a standard XRD card, it may be known that each sample has the same hexagonal phase structure without any phase separation. The stable crystal structure is propitious to improve stability of SET operation of the device.

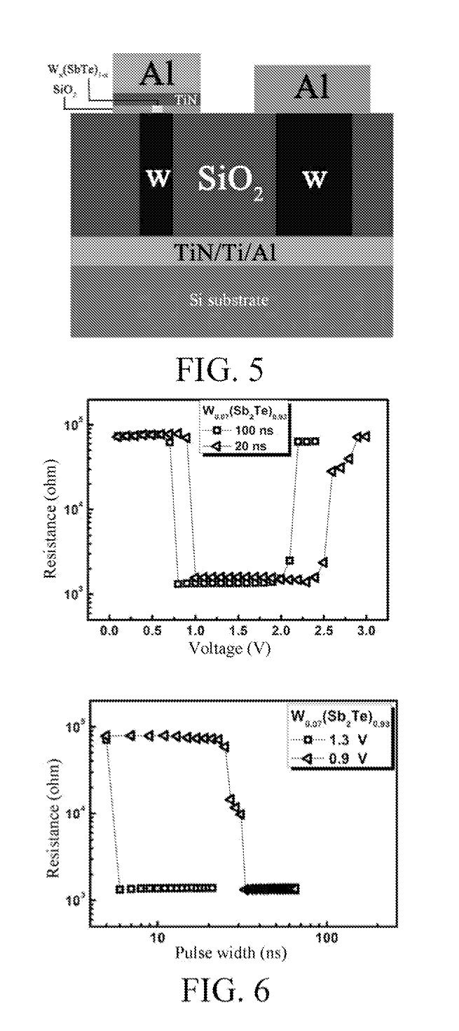

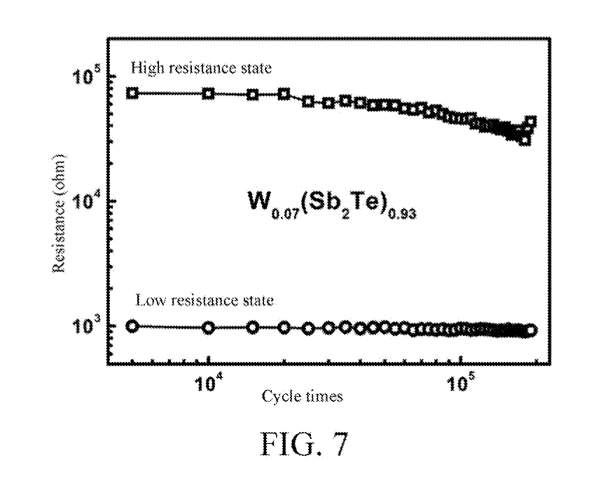

6. The c# sample has a suitable high and low resistance value difference and a suitable data holding capability, so that the c# sample is prepared to be a phase-change storage device with a limited T shape structure by using a 0.13 μm CMOS technique, then an electrical performance test is performed thereon, and a schematic structural diagram is shown in FIG. 5. FIG. 6 shows test results of resistance-voltage and resistance-pulse of the device unit. Under a voltage pulse of 20 ns, the device unit presents a characteristic of reversible phase-change, where an erase voltage and a write voltage are respectively 1 V and 2.7 V, a high resistance value is 46 times of a low resistance value. Further, the device may perform the SET operation under an effect of a pulse being 6 ns, which indicates that the c# sample may perform the phase-change quickly under an effect of a relatively low electric pulse, and a speed may achieve a level of a DRAM, and under the speed, the device may distinctly recognize “0” and “1”. FIG. 7 is a cycle life test of the device unit. It may be easily known from the drawing that under a relatively short and low voltage pulse, the device may stably and repeatedly work for more than 10⁵ times, and high and low resistance values nearly remain unchanged, thereby having good reliability.

### Embodiment 2

1. A Ti_{0.1}(Sb₂Te)_{0.9} thin film is prepared on a silicon substrate after being thermo-oxidized by using magnetron sputtering. A specific experiment method is that: single target sputtering is performed on prepared Ti_{0.1}(Sb₂Te)_{0.9}, a power is RF 30 W, a background vacuum degree is 1.8×10⁻⁴ Pa, an argon air pressure during sputtering is 0.19 Pa, and a thin film thickness is 200 nm.

2. An original position resistance-temperature test is performed on the Ti_{0.1} (Sb₂Te)_{0.9} thin film to obtain that a crystallization temperature is 225° C., and a data holding capability is calculated to be 137° C., where both of the two values are much higher than that of the Ge₂Sb₂Te₅ thin film.

3. A voltage change of the Ti_{0.1}(Sb₂Te)_{0.9} thin film before and after the phase-change is quite small, distribution of crystal grains are quite uniform, and phase splitting does not exist, so the Ti_{0.1} (Sb₂Te)_{0.9} thin film is quite suitable to be used in a high-speed and high-density memory.

To sum up, the present invention effectively overcomes various disadvantages in the prior art and has a high industrial use value.

The aforementioned embodiments only exemplarily illustrate the principle and the efficacy of the present invention instead of being used for limiting the present invention. Any person skilled in the art may modify or change the aforementioned embodiments without violating the spirit and the scope of the present invention. Therefore, all equivalent modifications or changes completed by persons having common sense in the technical field without departing from the spirit and the technical idea disclosed in the present invention should still be covered by claims of the present invention.

1. An antimony-rich high-speed phase-change material used in a phase-change memory (PCRAM), having a chemical formula being Aₓ(Sb₂Te)₁₋ₓ, x is an atom percent, wherein A is selected from W, Ti, Ta, and Mn, and 0<x<0.5.

2. The antimony-rich high-speed phase-change material used in a PCRAM as in claim 1, wherein 0<x<0.12.

3. The antimony-rich high-speed phase-change material used in a PCRAM as in claim 2, wherein the antimony-rich high-speed phase-change material is a single-phase W—Sb—Te material.

4. The antimony-rich high-speed phase-change material used in a PCRAM as in claim 1, wherein the antimony-rich high-speed phase-change material performs reversible phase-change under an effect of an electric pulse.

5. A preparing method of the antimony-rich high-speed phase-change material used in a phase-change memory (PCRAM) as in claim 1, selected from magnetron sputtering, chemical vapor deposition (CVD), atom-layer deposition, pulsed laser deposition, electron beam evaporation, and electroplating.

6. The preparing method of the antimony-rich high-speed phase-change material used in a PCRAM as in claim 5, wherein the magnetron sputtering of Wₓ(Sb₂Te)₁₋ₓ is that: a Wₓ(Sb₂Te)_{1 -x} thin film is prepared on a silicon substrate after being thermo-oxidized by using W and Sb₂Te dual-target co-sputtering, wherein during the co-sputtering, a background vacuum degree is 1.8-2.2×10⁻⁴ Pa, an argon air pressure during sputtering is 0.18-0.26 Pa, a sputtering power of the Sb₂Te target is radio frequency (RF) 20 W, and a sputtering power of the W target is RF 5-10 W.

7. An application of the antimony-rich high-speed phase-change material used in a phase-change memory (PCRAM) as in claim 1 in a phase-change thin film material field.

8. A phase-change storage device unit prepared by using the antimony-rich high-speed phase-change material used in a PCRAM as in claim 1.

9. A preparing method of the phase-change storage device unit as in claim 8, being a 0.13 μm complementary metal-oxide-semiconductor (CMOS) technique.

10. The preparing method of the phase-change storage device unit as in claim 9, comprising: depositing an SiO₂ dielectric layer with a thickness of 8-12 nm on a W electrode, making a small hole with a width of 8-12 nm on the SiO₂ dielectric layer right above the W electrode by using ion beam focusing, then filling the hole with the Wₓ(Sb₂Te)₁₋ₓ phase-change material by using chemical vapor deposition (CVD) or physical vapor deposition (PVD), and finally depositing a TiN adhesion layer with a thickness of 15-25 nm and an Al top electrode with a thickness of 290-310 nm by using the PVD.
